(19) United States
(12) Patent Application Publication
(10) Pub. No.: US 2026/0206546 A1
(43) Pub. Date: Jul. 16, 2026

(54) RECONSTITUTED STRUCTURES WITH TEST PADS

(71) Applicant: ADEIA SEMICONDUCTOR BONDING TECHNOLOGIES INC., San Jose, CA (US)

(72) Inventors: Patrick Variot, Los Gatos, CA (US); Rajesh Katkar, Milpitas, CA (US); Hong Shen, Palo Alto, CA (US); Belgacem Haba, Saratoga, CA (US)

(21) Appl. No.: 19/022,397

(22) Filed: Jan. 15, 2025

(51) Int. Cl. H01L 21/66; H01L 23/31

(52) U.S. Cl. CPC H10P 74/273; H10W 74/121

(57) ABSTRACT

A bonded structure is disclosed. The bonded structure can include a first device layer comprising a reconstituted element having a first die at least partially embedded in an encapsulant. The bonded structure can further include a second device layer comprising a second die bonded to the reconstituted element along a first bonding interface. The bonded structure can also include a first signal test trace positioned between the reconstituted element and the second die. The first signal test trace can be in electrical communication with at least one of the first die and the second die and can extend outwardly from the first bonding interface. The first signal test trace can be positioned such that during singulation of the bonded structure, a portion of the first signal test trace is removed along a cutting path and a remaining portion extends to an edge of the singulated bonded structure.

### BACKGROUND

### Field

This disclosure relates to semiconductor device structures and methods. In particular, some implementations are directed to methods and structures for testing of bonded structures via removeable test pads.

### Description of the Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Semiconductor devices have increased in complexity along with the need to test functionality of components. However, it can be challenging and time-consuming to determine the functionality of components after the assembly of a bonded structure. Accordingly, there remains a continuing demand for improved testing and methods.

### SUMMARY

For purposes of summarizing the disclosure and the advantages achieved over the prior art, certain objects and advantages of the disclosure are described herein. Not all such objects or advantages may be achieved in any particular implementation. Thus, for example, those skilled in the art will recognize that the devices, systems, and methods may be embodied or carried out in a manner that achieves or optimizes one advantage or group of advantages as taught herein without necessarily achieving other objects or advantages as may be taught or suggested herein.

All of these implementations are intended to be within the scope of the devices, systems, and methods herein disclosed. These and other implementations will become readily apparent to those skilled in the art from the following detailed description of the implementations having reference to the attached figures, the devices, systems, and methods not being limited to any particular implementations disclosed.

In some implementations, a bonded structure can include: a first device layer including a reconstituted element, the reconstituted element including a first die at least partially embedded in an encapsulant; a second device layer including a second die, the second die bonded to the reconstituted element along a first bonding interface; and a first signal test trace positioned between the reconstituted element and the second die, the first signal test trace in electrical communication with at least one of the first die and the second die, wherein the first signal test trace extends outwardly from the first bonding interface.

In some implementations, the first signal test trace is positioned between the first die and the second die. In some implementations, the second die is hybrid bonded to the reconstituted element. In some implementations, the second die of the second device layer is at least partially embedded in a second encapsulant. In some implementations, the first signal test trace is integrated into a redistribution bonding layer (RDL) between the reconstituted element and the second die. In some implementations, the bonded structure includes a cover die disposed over the second die.

In some implementations, the first signal test trace extends to an edge of the bonded structure. In some implementations, the first signal test trace is positioned such that during singulation of the bonded structure, a portion of the first signal test trace is removed along a cutting path, leaving a remaining portion of the first signal test trace within the singulated bonded structure such that the remaining portion of the first signal test trace extends to an edge of the singulated bonded structure. In some implementations, the first signal test trace includes a signal test pad connected to the first signal test trace, wherein the signal test pad is wider than the first signal test trace. In some implementations, the second die includes a die stack included of a plurality of dies.

In some implementations, the first signal test trace extends beyond functional areas of the first die and the second die. In some implementations, the reconstituted element of the first device layer further includes a third die and the second device layer further includes a fourth die, the fourth die bonded to the reconstituted element along a second bonding interface, wherein a second signal test trace is positioned between the reconstituted element and the fourth die, the second signal trace in electrical communication with at least one of the third die and the fourth die, and wherein the second signal test trace extends outwardly from the second bonding interface. In some implementations, the second signal test trace extends to an another edge of the bonded structure. In some implementations, the second signal test trace is positioned such that during a second singulation of the bonded structure, a removed portion of the second signal test trace is removed along a second cutting path, leaving a remaining portion of the second signal test trace within the second singulated bonded structure such that the remaining portion of the second signal test trace extends to an another edge of the second singulated bonded structure. In some implementations, the second signal test trace extends beyond functional areas of the third die and the fourth die.

In some implementations, a bonded structure can include: a first device layer including a reconstituted element, the reconstituted element including a first die at least partially embedded in an encapsulant; a second device layer including a die stack, the die stack bonded to the reconstituted element along a first bonding interface, wherein the die stack includes a plurality of dies; and a first signal test trace positioned between the reconstituted element and the die stack, the first signal trace in electrical communication with at least one of the first die and the die stack, wherein the first signal test trace extends outwardly from the first bonding interface.

In some implementations, the first signal test trace is positioned between the first die and the die stack. In some implementations, the die stack is hybrid bonded to the reconstituted element. In some implementations, the bonded structure includes a second encapsulant at least partially surrounding the die stack. In some implementations, the first signal test trace is integrated into a redistribution bonding layer (RDL) between the reconstituted element and the die stack.

In some implementations, the first signal test trace extends to an edge of the bonded structure. In some implementations, the first signal test trace is positioned such that during singulation of the bonded structure, a portion of the first signal test trace is removed along a cutting path, leaving a remaining portion of the first signal test trace within the singulated bonded structure such that the remaining portion of the first signal test trace extends to an edge of the singulated bonded structure. In some implementations, the first signal test trace further includes a signal test pad connected to the first signal test trace, wherein the signal test pad is wider than the first signal test trace. In some implementations, the first signal test trace extends beyond functional areas of the first die and the die stack.

In some implementations, the reconstituted element of the first device layer further includes a second die and the second device layer further includes a second die stack, the second die stack bonded to the second die along a second bonding interface, wherein a second signal test trace is positioned between the reconstituted element and the second die stack, the second signal test trace in electrical communication with at least one of the second die and the second die stack, and wherein the second signal test trace extends outwardly from the second bonding interface. In some implementations, the second signal test trace extends to an another edge of the bonded structure. In some implementations, the second signal test trace is positioned such that during a second singulation of the bonded structure, a removed portion of the second signal test trace is removed along a second cutting path, leaving a remaining portion of the second signal test trace within the second bonded structure such that the remaining portion of the second signal test trace extends to an another edge of the singulated bonded structure. In some implementations, the second signal test trace extends beyond functional areas of the second die and the second die stack.

In some implementations, a reconstituted structure can include: a first device layer including a reconstituted element, the reconstituted element including a first die at least partially embedded in a first encapsulant; a second device layer including a second die at least partially embedded in a second encapsulant, the second device layer bonded to the first device layer along a first bonding interface and; a third device layer including a third die, the third die bonded to the second device layer along a second bonding interface, wherein through-substrate-vias electrically connect at least one of first die and the second die; and a first signal test trace positioned between the second device layer and the third die, the first signal test trace in electrical communication with at least one of the first die, the second die, and the third die via the through-substrate-vias, wherein the first signal test trace extends outwardly from the second bonding interface.

In some implementations, the second device layer is hybrid bonded to the first reconstituted element. In some implementations, the third die is hybrid bonded to the second device layer. In some implementations, the first signal test trace is integrated into a redistribution bonding layer (RDL) between the second device layer and the third die. In some implementations, the first signal test trace extends to an edge of the bonded structure. In some implementations, the first signal test trace is positioned such that during singulation of the bonded structure, a removed portion of the first signal test trace is removed along a cutting path, leaving a remaining portion of the first signal test trace within the singulated bonded structure such that the remaining portion of the first signal test trace extends to an edge of the singulated bonded structure.

In some implementations, the first signal test trace further includes a signal test pad connected to the first signal test trace, wherein the signal test pad is wider than the first signal test trace. In some implementations, the first signal test trace extends beyond functional areas of the first die, the second die, and the third die.

In some implementations, the third die of the third device layer at least partially embedded in a third encapsulant; a fourth die bonded to the third device layer along a third bonding interface, wherein the through-substrate-vias electrically connect the first die, the second die, the third die, and the fourth die; and a second signal test trace positioned between the third device layer and the fourth die, the second signal test trace electrical communication with at least one of the first die, the second die, the third die, and the fourth die via the through-substrate-vias, wherein the second signal test trace extends outwardly from the third bonding interface. In some implementations, the second signal test trace extends to the edge of the bonded structure. In some implementations, the second signal test trace is positioned such that during singulation of the bonded structure, a removed portion of the second signal test trace is removed along a cutting path, leaving a remaining portion of the second signal test trace within the singulated bonded structure such that the remaining portion of the second signal test trace extends to the edge of the singulated bonded structure. In some implementations, the second signal test trace extends beyond functional areas of the first die, the second die, the third die, and the fourth die.

In some implementations, the first reconstituted element of the first device layer further includes a fifth die, the second device layer further includes a sixth die, and the third device layer includes a seventh die, wherein the sixth die is bonded to the reconstituted element along a fourth bonding interface and the seventh die is bonded to the second device layer along a fifth bonding interface, wherein through-substrate-vias electrically connect the fifth die, the sixth die, and the seventh die, wherein a third signal test trace is positioned between the second device layer and the seventh die, the third signal test trace in electrical with at least one of the fifth die, the sixth die, and the seventh die via the through-substrate-vias, and wherein the third signal test trace extends outwardly from the fifth bonding interface. In some implementations, the third signal test trace extends to an another edge of the bonded structure. In some implementations, the third signal test trace is positioned such that during a second singulation of the bonded structure, a removed portion of the third signal test trace is removed along a cutting path, leaving a remaining portion of the third signal test trace within the second singulated bonded structure such that the remaining portion of the third signal trace extends to an another edge of the singulated bonded structure. In some implementations, the third signal test trace extends beyond functional areas of the fifth die, the sixth die, and the seventh die.

In some implementations, an eighth die bonded to third device layer along a sixth bonding interface, wherein the through-substrate-vias electrically connect the fifth die, the sixth die, and the seventh die, and the eighth die; and a fourth signal test trace positioned between the third device layer and the eighth die and in electrical communication with at least one of the fifth die, the sixth die, the seventh die, and the eighth die via the through-substrate-vias, wherein the fourth signal test trace extends outwardly from the sixth bonding interface. In some implementations, the fourth signal test trace extends to the another edge of the bonded structure. In some implementations, the fourth signal test trace is positioned such that during a second singulation of the bonded structure, a portion of the fourth signal test trace is removed along a second cutting path, leaving a remaining portion of the fourth signal test trace within the second singulated bonded structure such that the remaining portion of the fourth signal test trace extends to the another edge of the singulated bonded structure. In some implementations, the fourth signal test trace extends beyond functional areas of the fifth die, the sixth die, the seventh die, and the eighth die.

In some implementations, a method for testing one or more dies of a bonded structure can include: providing a bonded structure including a first device layer having a reconstituted element including at least a first die at least partially embedded in an encapsulant, a second device layer including a second die bonded to the reconstituted element along a bonding interface, and a first signal test trace positioned between the reconstituted element and the second die, the first signal test trace in electrical communication with at least one of the first die and the second die, wherein the first signal test trace extends outwardly from the bonding interface; testing at least one of the first die and the second die via the first signal test trace; and removing a portion of the first signal test trace by singulating the bonded structure such that a remaining portion of the first signal test trace extends to an edge of the bonded structure.

In some implementations, testing includes probing the first signal test trace to determine known good die characteristics of at least one of the first die and the second die. In some implementations, the method includes measuring electrical properties of at least one of the first die and the second die via the first signal test trace; and analyzing the measured electrical properties to determine a quality of the first die and the second die. In some implementations, the at least one of the first die and the second die includes at least one of parametric probing, wafer acceptance test (WAT), process control monitoring (PCM), direct current (DC) probing, radio frequency (RF) probing, and open-short testing.

In some implementations, the testing at least one of the first die and the second die occurs after the bonding of the second die to the first die. In some implementations, the testing at least one of the first die and the second die occurs after hybrid bonding of the second die to the reconstituted element.

In some implementations, a method for testing one or more dies of a bonded structure can include: providing a bonded structure including a first device layer having a reconstituted element including a first die at least partially embedded in an encapsulant, a second device layer including a die stack bonded to the reconstituted element along a bonding interface, wherein the die stack includes a plurality of dies, and a first signal test trace positioned between the reconstituted element and the die stack, the first signal test trace in electrical communication with at least one of the first die and the die stack, wherein the first signal test trace extends outwardly from the bonding interface; testing at least one of the first die and the die stack via the first signal test trace; and removing a portion of the first signal test trace by singulating the bonded structure such that a remaining portion of the first signal test trace extends to an edge of the singulated bonded structure.

In some implementations, the testing includes probing the first signal test trace to determine known good die characteristics of at least one of the first die and the die stack. In some implementations, the method includes measuring electrical properties of the first die and the die stack via the first signal test trace; and analyzing the measured electrical properties to determine a quality of the first die and the die stack. In some implementations, the testing of at least one of the first die and the die stack includes at least one of parametric probing, wafer acceptance test (WAT), process control monitoring (PCM), direct current (DC) probing, radio frequency (RF) probing, and open-short testing. In some implementations, the testing at least one of the first die and the die stack occurs after the bonding of the die stack to the first die. In some implementations, the testing at least one of the first die and the die stack occurs after hybrid bonding of the die stack to the reconstituted element.

In some implementations, a method for testing one or more dies of a bonded structure can include: providing a bonded structure including a first device layer having a reconstituted element including a first die at least partially embedded in an encapsulant, a second device layer including a second die at least partially embedded in a second encapsulant, the second device layer bonded to the first reconstituted element along a first bonding interface, and a third die bonded to the second device layer along a second bonding interface, wherein through-substrate-vias electrically connect the first die and the second die, and a first signal test trace positioned between the second die and the third die, the first signal test trace in electrical communication with at least one of the first die, the second die, and the third die via the through-substrate-vias, wherein the first signal test trace extends outwardly from the second bonding interface; testing at least one of the first die, the second die, and the third die via the first signal test trace; and removing a portion of the first signal test trace by singulating the bonded structure such that a remaining portion of the first signal test trace extends to an edge of the singulated bonded structure.

In some implementations, testing includes probing the first signal test trace to determine known good die characteristics of the at least one of the first die, the second die, and the third die. In some implementations, the method includes measuring electrical properties of at least one of the first die, the second die, and the third die via the first signal test trace; and analyzing the measured electrical properties to determine a quality of the first die, the second die, and the third die. In some implementations, testing the at least one of the first die and the second die includes at least one of parametric probing, wafer acceptance test (WAT), process control monitoring (PCM), direct current (DC) probing, radio frequency (RF) probing, and open-short testing. In some implementations, the testing of the at least one of the first die, the second die, and the third die occurs after the bonding of the first reconstituted element, the second device layer, and the third die.

In some implementations, the testing at least one of the first die, the second die, and the third die occurs after hybrid bonding of the first reconstituted element, the second device layer, and the third die. In some implementations, the bonded structure being provided further includes the third die of the third device layer at least partially embedded in a third encapsulant, a fourth die bonded to the third device layer along a third bonding interface, wherein the through-substrate-vias electrically connect the first die and the fourth die, and a second signal test trace positioned between the third device layer and the fourth die, the second signal test trace in electrical communication with at least one of the first die, the second die, the third die, and the fourth die via the through-substrate-vias, wherein the second signal test trace extends outwardly from the third bonding interface and testing at least one of the first die, the second die, the third die, and the fourth die via the second signal test trace. In some implementations, the method includes removing a portion of the second signal trace by singulating the bonded structure such that a remaining portion of the second signal trace extends to the edge of the singulated bonded structure.

In some implementations, a method for forming a bonded structure can include: providing a first device layer having reconstituted element including a first die at least partially embedded in an encapsulant; bonding a second device layer including a second die to the reconstituted element along a bonding interface; and forming a first signal test trace positioned between the reconstituted element and the second die, the first signal test trace in electrical communication with at least one of the first die and the second die, wherein the first signal test trace extends outwardly from the bonding interface.

In some implementations, the first signal test trace is positioned between the first die and the second die. In some implementations, bonding the second die to the reconstituted element includes hybrid bonding. In some implementations, the method includes at least partially embedding the second die in a second encapsulant. In some implementations, the method includes integrating the first signal test trace into a redistribution bonding layer (RDL) between the reconstituted element and the second die.

In some implementations, the method includes disposing a cover die over the second die. In some implementations, the method includes singulating the bonded structure such that a removed portion of the first signal test trace is removed along a cutting path, leaving a remaining portion of the first signal test trace within the singulated bonded structure such that the remaining portion of the first signal test trace extends to an edge of the singulated bonded structure. In some implementations, the reconstituted element of the first device layer further includes a third die and the second device layer further includes a fourth die, the fourth die bonded to the reconstituted element along a second bonding interface, and forming a second signal test trace positioned between the reconstituted element and the fourth die, the second signal trace in electrical communication with at least one of the third die and the fourth die, wherein the second signal test trace extends outwardly from the second bonding interface.

In some implementations, the method includes singulating the bonded structure such that a removed portion of the second signal test trace is removed along a second cutting path, leaving a remaining portion of the second signal test trace within a second singulated bonded structure such that the remaining portion of the second signal test trace extends to an another edge of the singulated bonded structure. In some implementations, the second die includes a die stack included of a plurality of dies.

### BRIEF DESCRIPTION OF THE DRAWINGS

These and other features, aspects, and advantages of the disclosure are described with reference to drawings of certain implementations, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1 illustrates a schematic side sectional view of an example bonded structure, according to various implementations.

FIG. 2 illustrates another schematic side sectional view of the example bonded structure of FIG. 1, with cutting paths shown through the bonded structure.

FIG. 3 illustrates a schematic side sectional view of another example implementation of a bonded structure, according to various implementations.

FIG. 4 illustrates another schematic side sectional view of the bonded structure of FIG. 2, with cutting paths shown through the bonded structure.

FIG. 5 illustrates a schematic side sectional view of another example implementation of a bonded structure, according to various implementations.

FIG. 6 illustrates another schematic side sectional view of the example implementation of FIG. 5.

FIGS. 7A-7C illustrate various examples of signal test traces and signal test pad, according to various implementations.

FIG. 8A is a schematic cross-sectional side view of two elements prior to direct hybrid bonding.

FIG. 8B is a schematic cross-sectional side view of a bonded structure including the two elements shown in FIG. 8A after direct hybrid bonding.

### DETAILED DESCRIPTION

Although several implementations, examples, and illustrations are disclosed below, it will be understood by those of ordinary skill in the art that the devices, systems, and methods described herein extend beyond the specifically disclosed implementations, examples, and illustrations and includes other uses of the devices, systems, and methods and obvious modifications and equivalents thereof. Implementations are described with reference to the accompanying figures, wherein like numerals refer to like elements throughout. The terminology used in the description presented herein is not intended to be interpreted in any limited or restrictive manner simply because it is being used in conjunction with a detailed description of some specific implementations of the devices, systems, and methods. In addition, implementations can comprise several novel features. No single feature is solely responsible for its desirable attributes or is essential to practicing the devices, systems, and methods herein described.

The present disclosure may be understood by reference to the following detailed description. It is noted that, for purposes of illustrative clarity, certain elements in various drawings may not be drawn to scale, may be represented schematically or conceptually, or otherwise may not correspond exactly to certain physical configurations of implementations.

In semiconductor manufacturing, reconstituted structures—where individual dies are detached from their original wafers and reassembled into new configurations—are widely used in advanced packaging technologies. Ensuring the electrical integrity of these bonded structures is critical for device performance and reliability. Electrical testing methods are essential for detecting issues such as faulty connections, signal degradation, and/or shorts across the bonding interfaces.

Current electrical testing techniques for stacked structures include wafer probing, resistance measurements, and/or capacitance or inductance analysis. These methods help assess the quality of electrical connections between the dies and substrates, verify signal continuity, and detect defects like open circuits and/or shorts. Wafer probing, in particular, allows direct contact with bond pads and/or bump structures on the die. However, a significant challenge with current testing methods is that comprehensive electrical testing of all dies can only be performed after the bonding process is complete. This delay increases the risk of discovering defects late in the process, which can lead to higher costs due to rework or scraping. Furthermore, the increasing complexity of packaging designs and the shrinking dimensions of interconnects make it harder to ensure accurate testing, especially when dealing with a large number of dies bonded simultaneously. The waiting period before testing adds inefficiency, as any defects identified at this stage may cause the entire structure to be disassembled, leading to wasted time and/or resources. Thus, there is a continued need for an improved method for electrical testing of bonded structures with reconstituted dies. This approach enables earlier and more accurate detection of electrical faults, reduces testing times, and/or ensures reliable performance, all while minimizing damage to the bonded structures during testing.

Additionally, those testing methods may leave a relatively large residual signal test trace in a bonded structure, which can introduce some parasitic effects that adversely impact device performance. One effect is parasitic capacitance, in which the leftover signal test trace can create unintended capacitance between the trace and adjacent conductive structures, such as other traces or ground planes. This parasitic capacitance may degrade signal integrity, leading to delays and interference in high-frequency circuits. Additionally, the residual signal test trace can exhibit parasitic inductance, resulting in undesirable voltage drops during high-speed switching, which can further affect timing and signal performance. Furthermore, the proximity of leftover traces to active signal paths may lead to crosstalk, wherein signals from one trace interfere with another, potentially causing data errors and noise in sensitive circuits. Signal reflection is another concern, for example in high-speed or RF applications, as residual traces can disrupt the original signal, resulting in distorted waveforms or signal loss. Moreover, residual signal test traces may dissipate power as heat, contributing to inefficiencies, especially in power-sensitive applications. Additionally, unintended traces may act as antennas, emitting electromagnetic interference (EMI) that can affect nearby components, leading to further performance issues. A leftover trace can also cause impedance mismatches in transmission lines designed for specific impedance values, resulting in reflections and signal integrity problems.

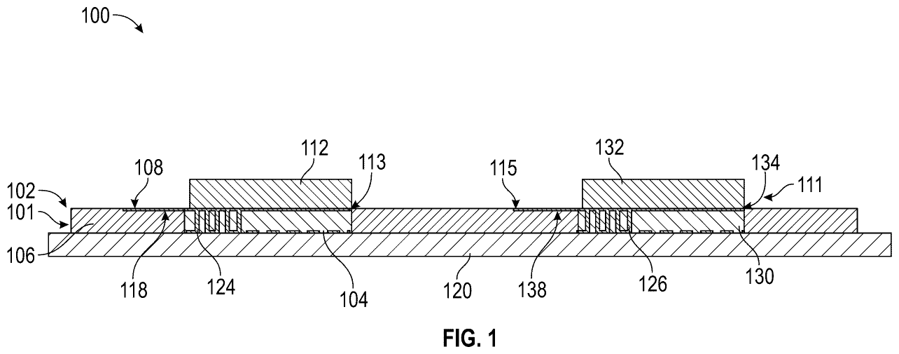

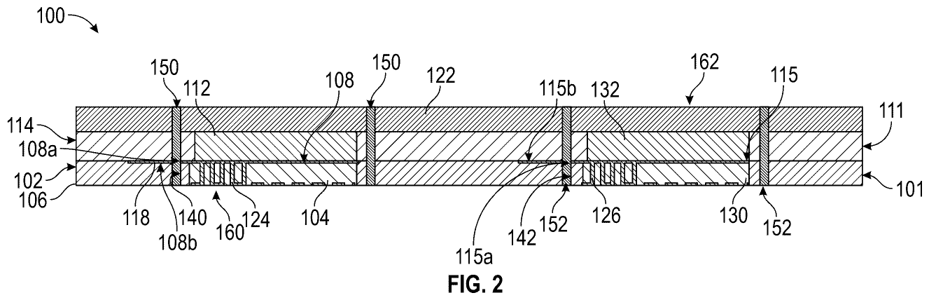

FIG. 1 illustrates a schematic side sectional view of a bonded structure 100. FIG. 2 illustrates another schematic side sectional view of the bonded structure 100 of FIG. 1 with cutting paths 150, 152 (also referenced herein as “saw streets” or “singulation paths”) shown through the bonded structure 100. As shown in FIG. 1, the bonded structure 100 can include a first device layer 101. The device layers are structured, functional layers integrated within a multi-layer assembly. The first device layer 101 can be comprised of a reconstituted element 102 formed by a reconstitution method (e.g., dies are reconstituted on a carrier wafer/panel and then the gap between the dies is filled with organic and/or inorganic dielectric). For example, the reconstituted element 102 can include a first die 104 at least partially embedded in a first encapsulant 106. The first encapsulant 106 of the reconstituted element 102 can be formed of organic material (e.g., epoxy molding compound, resin, etc.) or inorganic material (e.g., silicon oxide, silicon nitride, etc.). Additionally or alternatively, the first encapsulant 106 can comprise one or multiple inorganic dielectric layers (e.g., silicon oxide, silicon nitride, etc.). In some implementations, the one or more inorganic layers can comprise a first thin conformal layer (e.g., silicon nitride) and a second filling layer (e.g., silicon oxide). In other implementations, the first encapsulant 106 can comprise one or multiple organic layers (e.g., molding compound, epoxy, etc.).

A first redistribution layer (RDL) 108 can be formed on the backside of the reconstituted element 102, the backside opposite of a front side in which active devices and/or circuitry can be disposed, which can provide electrical connections. Through-substrate-vias 124 (TSVs) (e.g., through-silicon-vias, or TSVs) can extend through the first die 104 to connect the active devices and/or circuity at the front side with the backside of the reconstituted element 102. In some implementations, the reconstituted element 102 can be flipped such that the first RDL 108 is formed on the front side of the reconstituted element 102 rather than the backside of the reconstituted element 102. The first RDL 108 can facilitate the rerouting of electrical connections between the dies (e.g., the first die 104) and an external interface (e.g., a signal test trace). Additionally, the first RDL 108 can provide communication between the first die 104 and a second die 112 (e.g., to and/or from active circuitry of one die to another). The first RDL 108 can be applied (e.g., deposited) directly to these dies to reroute the electrical connections, enabling integration with external packaging and/or components as well as for testing. The first RDL 108 can be composed of one or more layers of conductive material that enable the redistribution of input/output (I/O) pads from their original positions to alternate locations, allowing for a wider pitch and improved connectivity to external components. The first RDL 108 can also comprise routing traces embedded in a dielectric material (e.g., inorganic dielectric like silicon oxide or an organic dielectric). The reconstituted element 102 can also be direct bonded and/or attached with an adhesive to a handle carrier 120. The handle carrier 120 can include a structured frame which securely engages and supports the reconstituted element 102, facilitating safe and efficient transport and positioning of the reconstituted element 102 during handling or processing.

The bonded structure 100 can further include a second device layer 111. The second device layer 111 can include a second die 112 bonded (e.g., direct bonded) to the reconstituted element 102. In some implementations, the second die 112 is a die stack comprised of a plurality of dies (e.g., a plurality of dies hybrid bonded in a stack). The second die 112 can be bonded to the reconstituted element 102 along a first bonding interface 113. For example, the second die 112 can comprise a bonding layer which can be bonded to a bonding layer deposited over the reconstituted element 102 (e.g., over both the first die 104 and the first encapsulant 106). The bonding layer of the reconstituted element 102 can either be disposed on top of or be part of the first RDL 108. In some implementations, the bonding layers can comprise prepared hybrid bonding surfaces and the second die 112 is hybrid bonded to the reconstituted element 102. The first bonding interface 113 can be aligned with and/or along the first RDL 108. In some implementations, the second die 112 is at least partially surrounded by a second encapsulant 114 (see FIG. 2).

The first RDL 108 of the bonded structure 100 can also comprise a first signal test trace. The first signal test trace can comprise a portion of the first RDL 108. The first signal test trace can be positioned on the backside of the reconstituted element 102 for testing of components of the bonded structure 100 (e.g., the first die 104 and/or the second die 112). The first signal test trace can be positioned between the reconstituted element 102 and the second die 112. The first signal test trace can be in electrical communication with at least one of the first die 104 and the second die 112. Additionally, as mentioned above, the TSVs 124 can extend through the first die 104 for providing communication between the first die 104 and the second die 112 (e.g., to and/or from active circuitry of one die to another). Additionally, the TSVs 124 can provide communication between the active devices and/or circuity disposed at the front side of the reconstituted element 102 (where the active circuitry is) and the first signal test trace of the first RDL 108.

The first RDL 108, which includes the first signal test trace, can extend outwardly from either direction of the first bonding interface 113. In some implementations, the first RDL 108 can include a signal test pad 118 connected (e.g., electrically connected) to the first test signal portion of the first RDL 108. The signal test pad 118 can have a width that is wider than the width of the first signal test trace, in some implementations. As mentioned above, the first signal test trace can be integrated into the first RDL 108 disposed along the backside of the reconstituted element 102 and between the reconstituted element 102 and the second die 112. In some implementations, the first signal test trace integrated into the first RDL 108 is positioned between the first die 104 and the second die 112. The first signal test trace, as well as the first RDL 108, can extend beyond the functional areas of the reconstituted element 102 and the second die 112 and/or beyond functional areas of the first die 104 and the second die 112. For example, the first signal test trace and the first RDL 108 can traverse interstitial regions between active components. Extending the first signal test trace over non-functional areas of the reconstituted element 102 (e.g., a portion of the first signal test trace extends over a non-die region of the reconstituted element 102, where no active circuitry is present beneath the first signal test trace) enables signal testing and/or monitoring of the active circuitry in the first device layer 101 and/or the second device layer 111. This allows the first signal test trace to be located not over any active circuitry of the reconstituted element 102 and/or second die 112, while enabling access to test signals without interfering with the core functional components. Additionally, this placement also ensures that the first signal test trace is out of the way of circuitry, allowing for removal during subsequent processing steps, such as die singulation. This arrangement can facilitate testing and can be eliminated without affecting the functional operation of the dies (e.g., first die 104 and/or second die 112).

The first RDL 108 comprising the first signal test trace can be utilized for a variety of testing methods, such as parametric probing, wafer acceptance test (WAT), and/or process control monitoring (PCM), to assess and monitor the quality and/or performance during assembly of the bonded structure 100. Parametric probing involves testing the electrical properties of semiconductor wafers (e.g., bonded structure 100) before the wafer is diced into individual device dies. Probes make contact with test structures (e.g., the first RDL 108 comprising the first signal test trace and/or signal test pad 118 of the bonded structure 100) of semiconductor devices to measure parameters like resistance, capacitance, and/or current. WAT evaluates the electrical performance of semiconductor devices after various stages of semiconductor manufacturing. WAT ensures that electrical specifications are satisfied, such as voltage thresholds, capacitance, and/or leakage, before the semiconductors are processed further and/or packaged. The results determine whether the semiconductor devices are accepted or rejected, helping ensure that only functional semiconductors continue in the production process. Lastly, PCM is a broader term that encompasses WAT and other tests used to monitor and control the semiconductor device manufacturing process. PCM data is collected throughout the production process to track performance and/or identify any deviations from the process parameters. PCM tracks the consistency and performance of manufacturing processes by testing specific structures fabricated on the semiconductor devices. In addition to the above testing methods, DC and/or RF probing can also be utilized. DC probing involves testing the low-frequency electrical characteristics of semiconductor devices, such as voltage, current, resistance, and/or capacitance during steady-state conditions. DC probing is used to evaluate basic electrical properties like transistor threshold voltage and leakage current, for example, during parametric testing. Probes make contact with pads on the semiconductor devices to perform these measurements, ensuring that the device functions as expected. RF probing is used to measure high-frequency signals, typically in the MHz to GHz range, in semiconductor devices. RF probing assesses parameters such as gain, return loss, and/or impedance to ensure the semiconductor device performs well at its operational frequency. Due to the sensitivity of high-frequency signals, RF probing setups have probes designed to minimize signal loss and reflections. Lastly, open-short testing can be used to detect faults in circuits, such as on printed circuit boards (PCBs) and cables, by identifying “opens” (breaks in continuity) and “shorts” (unintended connections between paths). The process involves sending signals through circuit paths of the semiconductor devices to confirm proper connectivity and/or isolation as needed.

By testing the bonded structure 100—for example, the first die 104 and/or second die 112—during assembly, and prior to applying encapsulant (e.g., silicon oxide, glass, etc.) protection and/or additional dies (e.g., first encapsulant 106 and/or cover die 122) while the bonded structure 100 is still attached to the handle carrier 120, offers several advantages, for example, related to quality control and/or early defect detection. Testing the first die 104 and/or second die 112 prior to applying encapsulant protection can assist with identifying defects in the semiconductor devices (e.g., bonded structure 100) before investing time and resources in further processing. Since oxide layers and/or encapsulants (e.g., first encapsulant 106 and/or second encapsulant 114) are typically added for protection and insulation, testing before their application enables problems to be caught early, reducing the number of non-functional and/or underperforming dies that make it through the later stages of production. If a defect is discovered after encapsulant layers are applied, rework and/or repair is more difficult, time-consuming, and/or expensive. Early testing helps to avoid wasting materials and process steps on faulty dies, leading to cost savings by filtering out defective units before they proceed through the rest of the production process. Before protective layers like encapsulants are applied, the electrical pads and contact points (e.g., the first RDL 108 comprising the first signal test trace and/or signal test pad 118) of the die(s) are more easily accessible for probing. This can simplify parametric testing, ensuring accurate electrical measurements can be taken without interference from additional layers that might affect probe contact or signal integrity. Testing at this stage provides feedback to the fabrication process of the bonded structure 100. For example, parameters like threshold voltage, and/or current leakage can be better monitored, and, if the results show any process drifts or anomalies, adjustments can be made in real-time to improve the overall manufacturing quality.

As shown in FIG. 2, a cover die 122 can be disposed over the second die 112. The cover die 122 can be positioned over a backside surface of the second die 112 that is opposite from the first die 104. In some implementations, the cover die 122 can be devoid of active circuity. In some implementations, the cover die 122 can include passive circuits such as resistors, capacitors, etc. The cover die 122 can protect the underlying dies (e.g., first die 104 and/or second die 112) from physical damage, contamination, and/or environmental stress while also providing mechanical support. Additionally, the handle carrier 120 can be detached (e.g., debonded) from the reconstituted element 102 such that a frontside of the first die 104 and the reconstituted element 102 is exposed. In some implementations, the cover die 122 comprises contacts on the exposed surfaces of the cover die 122 such that the bonded structure 100 including the cover die 122 can be bonded (e.g., direct bonded, soldered, etc.) to another structure (e.g., to a substrate, interposer, die, wafer, reconstituted element, etc.).

The bonded structure 100 can also be singulated along cutting paths 150, 152, for example, after testing, to form one or more singulated bonded structures 160, 162. During singulation of the bonded structure 100, the first RDL 108 comprising the first signal test trace can be positioned such that a removed portion 108b of first RDL 108 (e.g., a removed portion of the first signal test trace) is separated from the singulated bonded structure 160, and a remaining portion 108a of the first RDL 108 comprising the first signal test trace remains within the singulated bonded structure 160. The remaining portion 108a of the first RDL 108 comprising the first signal test trace can extend to the singulated edges 140 of the first singulated bonded structure 160 (e.g., the remaining portion 108a terminates at the boundary of the first encapsulant 106 such that the remaining portion 108a is flush with the edge of the first encapsulant 106). The removed portion 108b of the first RDL 108 comprising the first test signal can be the portion positioned over the interstitial space and/or outside the functional areas of the reconstituted element 102 and/or second die 112. The removed portion 108b that is removed along a cutting path 150 can also include the signal test pad 118. The first singulated bonded structure 160 can be diced (e.g., cut, sawed, etc.), leaving the remaining portion 108a within the singulated edges 140 of the singulated bonded structure 160 so that the remaining portion 108a extends to the singulated edge 140 of the singulated bonded structure 160. Singulation of the bonded structure 100 can occur after testing of the bonded structure 100. Various methods of dicing can be used for the singulation process of FIG. 2.

As show in FIGS. 1 and 2, in some implementations, the reconstituted element 102 of the first device layer 101 can include a third die 130, and the second device layer 111 can further include a fourth die 132. The fourth die 132 can be similar to or different from the second die 112. In some implementations, a second redistribution layer (RDL) 115 is also formed on the first device layer 101, which can be the same as or generally similar to First RDL 108. The second RDL 115 can facilitate the rerouting of electrical connections between the and/or among the dies (e.g., third die 130) and an external interface (e.g., a second test signal trace). The reconstituted element 102 can include any number of (e.g., tens, hundreds, thousands, etc.) of bonded structures comprising dies and redistribution layers having signal test traces. For example, the bonded structures can be formed on a wafer which is to be singulated into a plurality of singulated bonded structures.

The fourth die 132 can comprise a bonding layer which can be bonded to the reconstituted element 102 along a second bonding interface 134. For example, the fourth die 132 can comprise a bonding layer which can be bonded to a bonding layer deposited over the reconstituted element 102 (e.g., over both the third die 130 and the first encapsulant 106). The bonding layer of the reconstituted element 102 can either be disposed on top of or be part of the second RDL 115. In some implementations, the bonding layers can comprise prepared hybrid bonding surfaces and the fourth die 132 is hybrid bonded to the reconstituted element 102. The second bonding interface 134 can be aligned with and/or along the RDL 115.

The second RDL 115 of the bonded structure 100 can also include a second signal test trace. The second signal trace can comprise a portion of the second RDL 115. The second signal test trace of the second RDL 115, which can be similar or identical to the first signal test trace of the first RDL 108, can be positioned between the reconstituted element 102 and the fourth die 132. The second signal test trace can be in electrical communication with at least one of the third die 130 and the fourth die 132. Additionally, through-substrate-vias 126 (TSVs) (e.g., through-silicon-vias, or TSVs) can extend through the third die 130 for providing communication between the third die 130 and the fourth die 132 (e.g., to and/or from active circuitry of one die to another). Additionally, the substrate vias 126 can provide communication between the active devices and/or circuity disposed at the front side of the reconstituted element 102 (where the active circuitry is) and the second signal test trace of the second RDL 115.

The second RDL 115, which includes the second signal test trace, can extend outwardly from the second bonding interface 134. In some implementations, the second RDL 115 includes a signal test pad 138 connected (e.g., electrically connected) to the signal test trace portion of the second RDL 115. The signal test pad 138 can have a width that is wider than the width of the second signal test trace, in some implementations. The second signal test trace portion, portion, as well as the second RDL 115, can extend beyond the functional areas of the reconstituted element 102 and the fourth die 132 and/or beyond functional areas of the third die 130 and the fourth die 132. For example, the second RDL 115 can traverse interstitial regions between active components. Extending the second signal test trace over non-functional areas of the reconstituted element 102 (e.g., a portion of the second signal test trace extends over a non-die region of the reconstituted element 102, where no active circuitry is present beneath the second signal test trace) enables signal testing and/or monitoring of the active circuitry in the first device layer 101 and/or the second device layer 111. This allows the second signal test trace to be located not over any active circuitry of the reconstituted element 102 and/or fourth die 132, while enabling access to test signals without interfering with the core functional components. Additionally, this placement also ensures that the second signal test trace is out of the way of circuitry, allowing for removal during subsequent processing steps, such as die singulation. This arrangement can facilitate testing and can be eliminated without affecting the functional operation of the dies (e.g., third die 130 and/or fourth die 132).

Similar to first signal test trace, the second signal test trace can be utilized for a variety of testing methods, such as parametric probing, wafer acceptance test (WAT), and/or process control monitoring (PCM), to assess and monitor the quality and/or performance during assembly of the bonded structure 100. The second RDL 115 comprising the second signal test trace can be positioned such that during a second singulation of the bonded structure 100, which can occur simultaneously or after the first singulation, a removed portion 115b of the second RDL 115 is removed along second cutting paths 152, leaving a remaining portion 115a of the second RDL 115 comprising the second signal test trace within an another singulated edge 142 of the second singulated bonded structure 162. The remaining portion 115a of the second RDL 115 comprising the second signal test trace can extend to the another singulated edge 142 of the second singulated bonded structure 162 (e.g., the remaining portion 115a terminates at another boundary of the first encapsulant 106 such that the remaining portion 115a is flush with the edge of the first encapsulant 106). As shown in FIG. 2, after singulation, the two encapsulated device layers (e.g., first device layer 101 and second device layer 111) are flush with one another in part due to the first and/or second singulation along the first cutting paths 150 and second cutting paths 152. The remaining portions 108a of the first RDL 108 comprising the first signal test trace and the remaining portion 115a of the second RDL 115 comprising the second signal test trace can terminate at the flush edges of the singulated bonded structure 160 and second singulated bonded structure 162, respectively. In some implementations, the cover die 122 is also flush with all this. The singulated edges 140, 142 comprise a sawn surface with artifacts (e.g., striations or markings) indicative of a sawing process, or an etched surface with artifacts (e.g., slope or surface contours) indicative of an etching process.

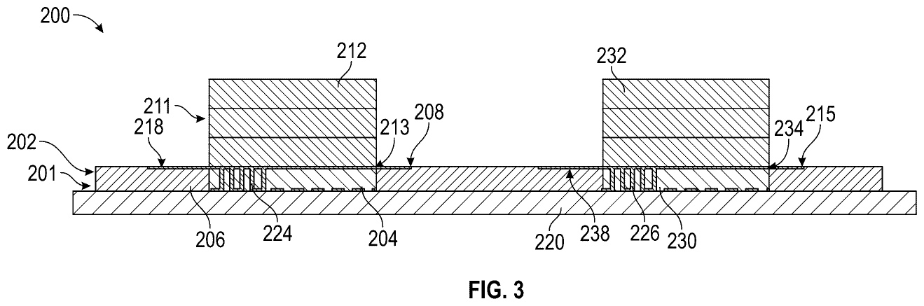

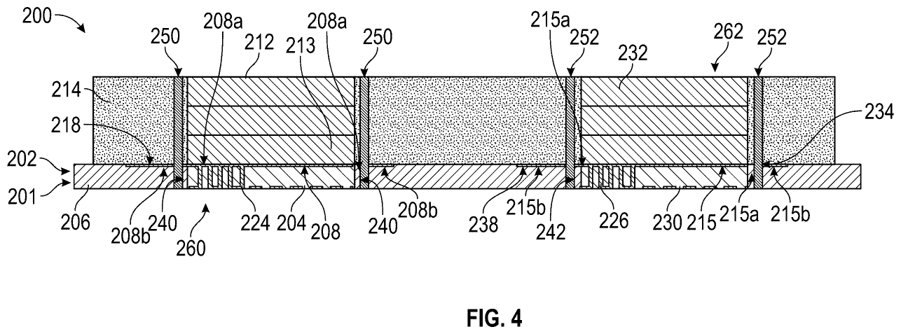

FIG. 3 illustrates a schematic side sectional view of another example implementation of a bonded structure 200. FIG. 4 illustrates another schematic side sectional view of the bonded structure 200 with cutting paths 250, 252 shown through the bonded structure 200. Unless otherwise noted, the components of FIGS. 3 and 4 can be the same as or generally similar to like-numbered components of FIGS. 1 and 2. For example, the bonded structure 200 can include a first device layer 201, a reconstituted element 202, first die 204, first encapsulant 206, fist RDL 208, second device layer 211, first bonding interface 213, second encapsulant 214, second RDL 215, signal test pad 218, handle carrier 220, through-substrate-vias 224 (TSVs), through-substrate-vias 226 (TSVs), second die 230, second bonding interface 234, and signal test pad 238. As shown in FIG. 3, the bonded structure 200 can include a first device layer 201 comprising a reconstituted element 202 having a first die 204 that is at least partially embedded in a first encapsulant 206. The first encapsulant 206 can comprise one or multiple inorganic dielectric layers (e.g., silicon oxide, silicon nitride, etc.). In some implementations, the one or more inorganic layers can comprise a first thin conformal layer (e.g., silicon nitride) and a second filling layer (e.g., silicon oxide). In other implementations, the first encapsulant 206 can comprise one or multiple organic layers (e.g., molding compound, epoxy, etc.). In some implementations, a first redistribution layer (RDL) 208 is also formed on the backside of the reconstituted element 102, which can provide electrical connections. The reconstituted element 202 can be direct bonded and/or attached with an adhesive to a handle carrier 220.

The bonded structure 200 can further include a second device layer 211. The second device layer 211 can include a first die stack 212 comprised of a plurality of dies bonded (e.g., direct bonded) to the reconstituted element 202. The first die stack 212 can include multiple semiconductor dies arranged in a vertically stacked configuration to optimize space efficiency and enhance performance. Each die within first die stack 212 can be interconnected through through-silicon-vias (TSVs) or other high-density interconnects, allowing for efficient data transfer and reduced latency between dies. The first die stack 212 can support integration of various functional layers, such as processing, memory, or power management, within a single, compact module. The first die stack 212 can be bonded to the reconstituted element 202 along a first bonding interface 213. For example, the first die stack 212 can comprise a bonding layer which can be bonded to a bonding layer deposited over the reconstituted element 202 (e.g., over both the first die 204 and the first encapsulant 206). The bonding layer of the reconstituted element 202 can either be disposed on top of or be part of the first RDL 208. In some implementations, the bonding layers can comprise prepared hybrid bonding surfaces and the first die stack 212 is hybrid bonded to the reconstituted element 202. The first bonding interface 213 can be aligned with and/or along the first RDL 208. In some implementations, the first die stack 212 is at least partially surrounded by a second encapsulant 214 (see FIG. 4). The second encapsulant 214 can be formed of organic material (e.g., epoxy molding compound, resin, etc.) or inorganic material (e.g., silicon oxide, silicon nitride, etc.). The second encapsulant 214 can comprise the same type of material as the first encapsulant 206, or a different type of material. For example, the first encapsulant 206 can comprise an inorganic layer(s), and second encapsulant 214 can comprise an organic layer(s).

The first RDL 208 of the bonded structure 200 can also include a first signal test trace. The first signal test trace can be a portion of the first RDL 208. The first signal test trace can be positioned on the backside of the reconstituted element 202 for testing of components of the bonded structure 200 (e.g., first die 204 and/or first die stack 212). The first RDL 208 comprising the first signal test trace can be positioned between the reconstituted element 202 and the first die stack 212. The first signal test trace can be in electrical communication with at least one of the first die 204 and the first die stack 212. Additionally, through-substrate-vias 224 (TSVs) (e.g., through-silicon-vias, or TSVs) can extend through the first die 204 for providing communication between the first die 204 and the first die stack 212 (e.g., to and/or from active circuitry of one die to another). Additionally, the substrate vias 224 can provide communication between the active devices and/or circuity disposed at the front side of the reconstituted element 202 (where the active circuitry is) and the first signal test trace of the first RDL 208.

The first RDL 208, which includes the first signal test trace, can extend outwardly from either direction of the first bonding interface 213. In some implementations, the first RDL 208 can include a signal test pad 218 connected (e.g., electrically connected) to the first signal test trace portion of the first RDL 208. The signal test pad 218 can have a width that is wider than the width of the first signal test trace, in some implementations. As mentioned above, the first signal test trace can be integrated into the first RDL 208 disposed along the backside of the reconstituted element 202 and between the reconstituted element 202 and the first die stack 212. In some implementations, the first signal test trace integrated into the first RDL 208 is positioned between the first die 204 and the first die stack 212. The first signal test trace, as well as the first RDL 208, can extend beyond functional areas of the reconstituted element 202 and the first die stack 212 and/or beyond functional areas of the first die 204 and the first die stack 212. Similar to first signal test trace of the first RDL 108, the first signal test trace of the first RDL 208 can be utilized for a variety of testing methods, such as parametric probing, wafer acceptance test (WAT), and/or process control monitoring (PCM), to assess and monitor the quality and/or performance during assembly of the bonded structure 100.

As shown in FIG. 4, the handle carrier 220 can be detached (e.g., debonded) from the reconstituted element 202 of the first device layer 201 such that a frontside of the first die 204 and the reconstituted element 202 is exposed. The bonded structure 200 can be singulated, for example, after testing, to form one or more singulated bonded structures 260. During singulation of the bonded structure 200, the first RDL 208 comprising the first signal test trace can be positioned such that a removed portions 208b of the first RDL 208 (e.g., a removed portion of the first signal test trace) is separated from the singulated bonded structure 260, and a remaining portions 208a of the first RDL 208 comprising the first signal test trace remains within the singulated bonded structure 260, such that the remaining portion 208a extends to the either and/or both singulated edges 240 of the singulated bonded structure 260 (e.g., the remaining portion 208 a terminates at the boundary of the first encapsulant 206 such that the remaining portion 208 a is flush with the edge of the first encapsulant 206). The removed portion 208b can be the portion positioned over the interstitial space and/or outside the functional areas of the reconstituted element 202 and/or first die stack 212. The removed portion 208b can be composed of the signal test pad 218 that is removed along a cutting paths 250. The singulated bonded structure 260 can be diced (e.g., cut, sawed, etc.), leaving the remaining portion 208a of the first RDL 208 comprising the first signal test trace within the singulated edges 240 of the singulated bonded structure 260 so that the remaining portion 208a extends to the singulated edges 240 of the singulated bonded structure 260. Singulation of the bonded structure 200 can occur after testing of the bonded structure 200. As mentioned above, various methods can be used for the singulation process of FIG. 4.

As show in FIGS. 3 and 4, in some implementations, the reconstituted element 202 of the first device layer 201 includes a second die 230, and the second device layer 211 can further include a second die stack 232. The second die stack 232 can be similar to or different from the first die stack 212. In some implementations, the second die stack 232 can comprise a stack of memory dies and the second die 230 can comprise a processor die in electrical communication with the second die stack 232 comprised of memory dies. A second redistribution layer (RDL) 215 can also formed on the first device layer 201, which can be the same as or generally similar to RDL 208. The second RDL 215 can facilitate the rerouting of electrical connections between and/or among the dies (e.g., third die 230 and second die stack 232) and an external interface (e.g., a second test signal trace).

The second die stack 232 can be bonded to the reconstituted element 202 along a second bonding interface 234. For example, the second die stack 232 can comprise a bonding layer which can be bonded to a bonding layer deposited over the reconstituted element 202 (e.g., over both the second die 230 and the first encapsulant 206). The bonding layer of the reconstituted element 202 can either be disposed on top of or be part of the second RDL 215. In some implementations, the bonding layers can comprise prepared hybrid bonding surfaces and the second die stack 232 is hybrid bonded to the reconstituted element 202. The second bonding interface 234 can be aligned with and/or along the second RDL 215.

The second RDL 215 of the bonded structure 200 can also include a second signal test trace. The reconstituted element 202 can include any number of (e.g., tens, hundreds, thousands, etc.) of bonded structures comprising dies and redistribution layers having signal test traces. The second RDL 215 comprising the second signal test trace, which can be similar or identical to the first RDL 208 comprising the first signal test trace, can be positioned between the reconstituted element 202 and the second die stack 232 and in electrical communication with at least one of the second die 230 and the second die stack 232 via the through-substrate-vias 226 (TSVs) (e.g., through silicon vias, or TSVs). Additionally, TSVs 226 can extend through the second die 230 for providing communication between the second die 230 and the second die stack 232 (e.g., to and/or from active circuitry of one die to another). The second signal test trace can extend outwardly from the second bonding interface 234. In some implementations, the second signal test trace includes a signal test pad 238 connected to the signal test trace. The signal test pad 238 can have a width that is wider than the width of the signal test trace. The second signal test trace of the can extend beyond the functional areas of the reconstituted element 202 and the second die stack 232 and/or beyond functional areas of the second die 230 and the second die stack 232. For example, the RDL 215 comprising the second signal test trace can traverse interstitial regions between active components. Similar to first signal test trace of the first RDL 208, the second RDL 215 comprising the second signal test trace can be utilized for a variety of testing methods, such as parametric probing, wafer acceptance test (WAT), and/or process control monitoring (PCM), to assess and monitor the quality and/or performance during assembly of the bonded structure 100.

The RDL 215 having the second signal test trace can be positioned such that during a second singulation of the bonded structure 200, which can occur simultaneously or after the first singulation, a removed portion 215b of the second RDL 215 comprising the second signal test trace is removed along a second cutting path 252, leaving a remaining portion 215a of the second RDL 215 comprising the second signal test trace within an another singulated edges 242 of the second singulated bonded structure 262. The remaining portion 215a of the second signal test trace can thus extend to the another singulated edge 242 of the second singulated bonded structure 262 (e.g., the remaining portion 215a terminates at another boundary of the first encapsulant 206 such that the remaining portion 215a is flush with the edge of the first encapsulant 206). As shown in FIG. 4, after singulation, the two encapsulated device layers (e.g., first device layer 201 and second device layer 211) are flush with one another in part due to the first and/or second singulation along the first cutting paths 250 and second cutting paths 252. The remaining portions 208a of the first RDL 208 comprising the first signal test trace and the remaining portion 215a of the second RDL 215 comprising the second signal test trace can terminate at the flush edges of the singulated bonded structure 260 and second singulated bonded structure 262, respectively. The singulated edges 240, 242 comprise a sawn surface with artifacts (e.g., striations or markings) indicative of a sawing process, or an etched surface with artifacts (e.g., slope or surface contours) indicative of an etching process.

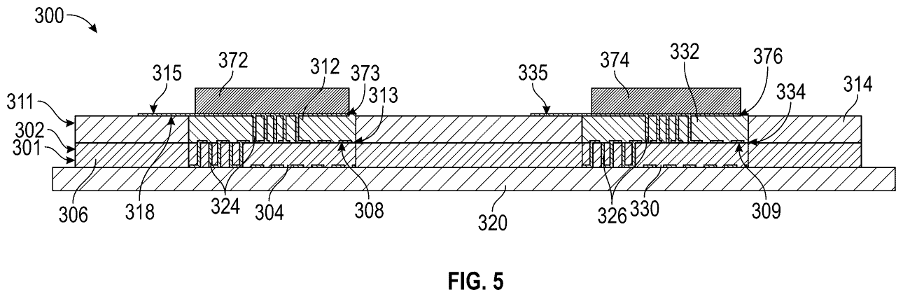

FIG. 5 illustrates a schematic side sectional view of another example implementation of a bonded structure 300. Unless otherwise noted, the components of FIG. 5 can be the same as or generally similar to like-numbered components of FIGS. 1 to 4. For example, the bonded structure 300 can include a first device layer 301, a reconstituted element 302, a first die 304, a first encapsulant 306, an RDL 308, a second device layer 311, a second die 312, a first bonding interface 313, a second encapsulant 314, a second RDL 315, a first signal test pad 318, a handle carrier 320, through-substrate-vias (TSVs) 324, through-substrate-vias (TSVs) 326, fifth die 330, fourth bonding interface 334, fifth RDL 335, and second signal test pad 338. As shown in FIG. 5, the bonded structure 300 can include a first device layer 301 comprising a reconstituted element 302 having a first die 304 that is at least partially embedded in a first encapsulant 306. The first encapsulant 306 can comprise one or multiple inorganic dielectric layers (e.g., silicon oxide, silicon nitride, etc.). In some implementations, the one or more inorganic layers can comprise a first thin conformal layer (e.g., silicon nitride) and a second filling layer (e.g., silicon oxide). In other implementations, the first encapsulant 306 can comprise one or multiple organic layers (e.g., molding compound, epoxy, etc.). The reconstituted element 302 can be formed atop a handle carrier 320. In some implementations, a redistribution layer (RDL) 308 is also formed on the backside of the reconstituted element 302, which can provide electrical connections. The first encapsulant 306 can comprise one or multiple inorganic dielectric layers (e.g., silicon oxide, silicon nitride, etc.).

A first redistribution layer (RDL) 308 can be formed (e.g., deposited) on the backside of the reconstituted element 302, the backside opposite of a front side in which active devices and/or circuitry can be disposed, which can provide electrical connections. Through-substrate-vias 324 (TSVs) (e.g., through-silicon-vias, or TSVs) can extend through the first die 304 to connect the active devices and/or circuity at the front side with the backside of the reconstituted element 302. In some implementations, the reconstituted element 302 can be flipped such that the first RDL 308 is formed on the front side of the reconstituted element 302 rather than the backside of the reconstituted element 302. The first RDL 308 can facilitate the rerouting of electrical connections between the dies (e.g., the first die 304) and an external interface (e.g., a signal test trace). Additionally, the first RDL 308 can provide communication between the first die 304 and a second die 312 (e.g., to and/or from active circuitry of one die to another).

The bonded structure 300 can further include a second device layer 311. The second device layer 311 can include a second die 312. The second die 312 can be at least partially surrounded by a second encapsulant 314. The second device layer 311 can comprise a bonding layer which can be bonded (e.g., direct bonded) to the reconstituted element 302 of the first device layer 301 along a first bonding interface 313. For example, the second die 312 can be bonded to a bonding layer deposited over the reconstituted element 302 (e.g., over both the first die 304 and the first encapsulant 306). The bonding layer of the reconstituted element 302 can either be disposed on top of or be part of a first RDL 308. The first bonding interface 313 can be along the first RDL 308. In some implementations, the second device layer 311 is hybrid bonded to the reconstituted element 302. In some implementations, the bonding layers comprises prepared hybrid bonding surfaces and the second device layer 311 is hybrid bonded to the reconstituted element 302. In some implementations, a second redistribution layer (RDL) 315 is also formed (e.g., deposited) on the second device layer 311, which can be the same as or generally similar to the first RDL 308. The second RDL 315 can facilitate the rerouting of electrical connections between the dies (e.g., second die 312) and an external interface (e.g., a second signal test trace).

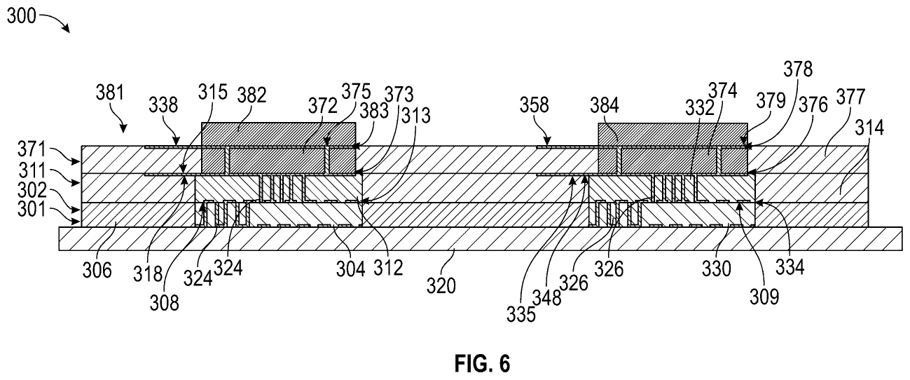

The bonded structure 300 can further include a third device layer 371. The third device layer 371 can include a third die 372 bonded (e.g., direct bonded) to the second device layer 311 along a second bonding interface 373. In some implementations, the third die 372 is a die stack comprised of a plurality of dies (e.g., a plurality of dies hybrid bonded in a stack). The third bonding interface 373 can be aligned with and/or along the second RDL 315. For example, the third die 372 can comprise a bonding layer which can be bonded to a bonding layer deposited over the second device layer 311 (e.g., over both the second die 312 and the second encapsulant 314). The bonding layer of the second device layer 311 can either be disposed on top of or be part of the second RDL 315. In some implementations, the bonding layers can comprise prepared hybrid bonding surfaces and the third die 372 is hybrid bonded to the second device layer 311. The TSVs 324 can electrically connect at least one of first die 304, the second die 312, and the third die 372. In some implementations, the third die 372 is at least partially surrounded by a second encapsulant 314 (see FIG. 6).

The second RDL 315 of the bonded structure 300 can also comprise a first signal test trace. The first signal test trace can a portion of the second RDL 315. The first signal test trace can be positioned on the backside of the second device layer 311 for testing of components of the bonded structure 300 (e.g., first die 304, second die 312, and/or third die 372). The second RDL 315 comprising the first signal test trace can be positioned between the second device layer 311 and the third die 372. The first signal test trace can be in electrical communication with at least one of the first die 304, the second die 312, and/or third die 372. Additionally, as mentioned above, the TSVs 324 (can extend through the first die 304 and/or second die 312 for providing communication between the first die 304, the second die 312, and/or the third die 372 (e.g., to or from active circuitry of one die to another).

The second RDL 315 comprising the first signal test trace can extend outwardly from either direction of the third bonding interface 373. In some implementations, the second RDL 315 can include a first signal test pad 318 connected (e.g., electrically connected) to the first signal test trace portion of the second RDL 315. The first signal test pad 318 can have a width that is wider than the width of the first signal test trace, in some implementations. The first signal test trace can be integrated into second RDL 315 disposed along the backside surface of the second device layer 311 and between the second device layer 311 and the third die 372. In some implementations, the first signal test trace is positioned between the second die 312 and the third die 372. The first signal test trace, as well as the second RDL 315, can extend beyond functional areas of the reconstituted element 302, the second device layer 311, and the third die 372 and/or beyond functional areas of the first die 304, the second die 312, and/or the third die 372. For example, second RDL 315 comprising the first signal test trace can traverse an interstitial region between active components. Extending the first signal trace over non-functional areas of the reconstituted element 302 and second device layer 311 (e.g., a portion of the first signal test trace extends over a non-die region of the reconstituted element 302 and second device layer 311, where no active circuitry is present beneath the first signal test trace) enables the first signal test trace to facilitate signal testing and/or monitoring at points outside the active circuitry of the reconstituted element 302, the second die 312, and/or third die 372, while enabling access to test signals without interfering with the core functional components. This placement also ensures that the first signal test trace is out of the way of circuitry, allowing for removal during subsequent processing steps, such as die singulation, with little to no impact on the performance or integrity of the adjacent dies (e.g., the first die 304, the second die 312, and/or the third die 372). This arrangement can facilitate efficient testing and can be eliminated without affecting the functional operation of the dies. The first RDL 308 comprising first signal test trace can also extend outwardly from either direction of the third bonding interface 373. Similar to the RDLs 108, 208 comprising the first signal test traces, the first RDL 308 comprising first signal test trace can be utilized for a variety of testing methods, such as parametric probing, wafer acceptance test (WAT), and/or process control monitoring (PCM), to assess and monitor the quality and/or performance during assembly of the bonded structure 300.

During singulation of the bonded structure 300, the handle carrier 320 can be detached (e.g., debonded) from the reconstituted element 302 of the first device layer 301 such that a frontside of the first die 304 and the reconstituted element 302 is exposed. The bonded structure 300 can be singulated, for example, after testing, to form one or more singulated bonded structures. During singulation of the bonded structure 300, second RDL 315 comprising the first signal test trace can be positioned such that a removed portion of the second RDL 315 (e.g., a removed portion of the first signal test trace) is separated from the singulated bonded structure, and a remaining portions of the second RDL 315 comprising the first signal test trace remains within the singulated bonded structure (e.g., the remaining portion of the first signal trace terminates at the boundary of the second encapsulant 314 such that the remaining portion is flush with the edge of the second encapsulant 314). The remaining portion of the second RDL 315 comprising the first signal test trace can extend to either and/or both edges of the singulated bonded structure. The removed portion can be the portion positioned over the interstitial space and/or outside the functional areas of the reconstituted element 302, the second die 312, and/or the third die 372. The removed portion can be composed of the first signal test pad 318 that is removed along a cutting path. The singulated bonded structure can be diced (e.g., cut, sawed, etc.), leaving the remaining portion of the second RDL 315 comprising the first signal test trace within the edges of the singulated bonded structure so that the remaining portion extends to the edges of the singulated bonded structure. Singulation of the bonded structure 300 can occur after testing of the bonded structure 300. As mentioned above, various methods can be used for the singulation process of FIG. 5.

FIG. 6 illustrates another schematic side sectional view of the example implementation of the bonded structure 300. As shown in FIG. 6, the third die 372 of the third device layer 371 can be at least partially embedded in a third encapsulant 377. A fourth device layer 381 having a fourth die 382 can be bonded to the third device layer 371 along a third bonding interface 383. While four device layers are shown, the bonded structure 300 can comprise any suitable number of device layers, e.g., more than four. The TSVs 324 can electrically connect the first die 304 and the fourth die 382. In some implementations, a third redistribution layer (RDL) 375 is also formed on the backside of the third device layer 371, which can be the same as or generally similar to the first RDL 308 and/or the second RDL 315. The third RDL 375 can facilitate the rerouting of electrical connections between and/or among the dies (e.g., third die 372) and an external interface (e.g., a third signal test trace).

The third RDL 375 of the bonded structure 300 can also include a second signal test trace. The second signal test trace can be positioned on the third device layer 371 for testing of components of the bonded structure 300 (e.g., first die 304, second die 312, third die 372, and/or fourth die 382). The third RDL 375 comprising the second signal test trace can be positioned between the third device layer 371 and the fourth die 382. The second signal test trace can be in electrical communication with at least one of the first die 304, the second die 312, the third die 372, and/or the fourth die 382 via the TSVs 324. The third RDL 375 comprising the second signal test trace can extend outwardly from the third bonding interface 383 in either direction of the third bonding interface 383. In some implementations, the third RDL 375 includes a second signal test pad 338 connected (e.g., electrically connected) to the second signal test trace portion of the third RDL 375. The second signal test pad 338 can have a width that is wider than the width of the second signal test trace, in some implementations. The second signal test trace can be integrated into third RDL 375 disposed along the third device layer 371 and between the third device layer 371 and the fourth die 382. In some implementations, the second signal test trace integrated into the third RDL 375 is positioned between the third die 372 and the fourth die 382. The third RDL 375 comprising the second signal test trace can extend beyond functional areas of the third device layer 371 and the fourth die 382 and/or beyond functional areas of the third die 372 and the fourth die 382. Additionally, the third RDL 375 comprising the second signal test trace can extend beyond functional areas of the first die 304, the second die 312, the third die 372, and the fourth die 382. Similar to first signal test trace of the second RDL 315, the second signal test trace of the third RDL 375 can be utilized for a variety of testing methods, such as parametric probing, wafer acceptance test (WAT), and/or process control monitoring (PCM), to assess and monitor the quality and/or performance during assembly of the bonded structure 300.

Although not shown, during singulation of the bonded structure 300 along one or more cutting paths as described above, the third RDL 375 comprising the second signal test trace can be positioned such that a removed portion of the third RDL 375 is separated from the singulated bonded structure at the cutting paths, and a remaining portions of the third RDL 375 remains within the singulated bonded structure (e.g., the remaining portion of the second signal test trace terminates at the boundary of the third encapsulant 377 such that the remaining portion is flush with the edge of the third encapsulant 377). The remaining portion of the third RDL 375 comprising the second signal test trace can extend to either and/or both edges of the singulated bonded structure. The removed portion can be the portion positioned over the interstitial space and/or outside the functional areas of the reconstituted element 302, the second die 312, the third die 372, and/or the fourth die 382. The removed portion of third RDL 375 comprising the can be comprised of the second signal test pad 338 that is removed along a cutting path. The singulated bonded structure can be diced (e.g., cut, sawed, etc.), leaving the remaining portion of the third RDL 375 comprising the second signal test trace within the edges of the singulated bonded structure so that the remaining portion extends to the edges of the singulated bonded structure. Singulation of the bonded structure 300 can occur after testing of the bonded structure 300. As mentioned above, various methods can be used for the singulation process of FIG. 6.

Referring back to FIG. 5, in some implementations, the first reconstituted element 302 of the first device layer 301 can further include a fifth die 330, and the second device layer 311 can further include a sixth die 332. The sixth die 332 can be similar to or different from the second die 312. In some implementations, a fourth redistribution layer (RDL) 309 is also formed on the first device layer 301, which can be the same as or generally similar to RDL 308. The fourth RDL 309 can facilitate the rerouting of electrical connections between the dies (e.g., fifth die 330) and an external interface. The sixth die 332 can be bonded to the reconstituted element 302 along a fourth bonding interface 334. For example, the sixth die 332 can comprise a bonding layer which can be bonded to a bonding layer deposited over the reconstituted element 302 (e.g., over both the fifth die 330 and the first encapsulant 306). In some implementations, the bonding layers can comprise prepared hybrid bonding surfaces and the sixth die 332 is hybrid bonded to the reconstituted element 302. The fourth bonding interface 334 can be aligned with and/or along the fourth RDL 309.

Additionally, the third device layer 371 can further include a seventh die 374. The seventh die 374 can be similar to or different from the second die third die 372. In some implementations, a fifth redistribution layer (RDL) 335 is also formed (e.g., deposited) on the second device layer 311, which can be the same as or generally similar to second RDL 315. The fifth RDL 335 can facilitate the rerouting of electrical connections between the dies (e.g., sixth die 332) and an external interface (e.g., a third signal test trace). The seventh die 374 can be bonded to the second device layer 311 along a fifth bonding interface 376. Through-substrate-vias 326 (TSVs) (e.g., through-silicon-vias, or TSVs) can extend through the fifth die 330 and/or the sixth die 332 for providing communication between the fifth die 330 and the seventh die 374 (e.g., to or from active circuitry of one die to another).

The fifth RDL 335 of the bonded structure 300 can include a third signal test trace, which can be similar to the first signal test trace of the second RDL 315 and/or the second signal test trace of the third RDL 375. The third signal test trace can be positioned between the second device layer 311 and the seventh die 374 and in electrical communication with at least one of the fifth die 330, the sixth die 332, and the seventh die 374 via the TSVs 326. The fifth RDL 335 comprising the third signal test trace can extend outwardly from the fifth bonding interface 376. In some implementations, the fifth RDL 335 includes a signal test pad 348 connected (e.g., electrically connected) to the second signal test trace. The signal test pad 348 can have a width that is wider than the width of the second signal test trace, in some implementations. The fifth RDL 335 comprising the third signal test trace can extend beyond functional areas of the second device layer 311 and the seventh die 374 and/or beyond functional areas of the sixth die 332 and the seventh die 374. Additionally, the fifth RDL 335 comprising the third signal test trace can extend beyond functional areas of the fifth die 330, the sixth die 332, and the seventh die 374. Similar to second RDL 315 comprising the first signal test trace and the third RDL 375 comprising the second signal test trace, the fifth RDL 335 comprising the third signal test trace can be utilized for a variety of testing methods, such as parametric probing, wafer acceptance test (WAT), and/or process control monitoring (PCM), to assess and monitor the quality and/or performance during assembly of the bonded structure 300. The third signal test trace can be positioned such that during a second singulation of the bonded structure 300, which can occur simultaneously or after the first singulation, a portion of the fifth RDL 335 comprising the third signal test trace is removed along a second cutting path, leaving a remaining portion of the fifth RDL 335 comprising the third signal test trace within an another edge of the second singulated bonded structure (e.g., the remaining portion of the third signal test trace terminates at another boundary of the second encapsulant 314 such that the remaining portion is flush with the edge of the second encapsulant 314). The remaining portion of the fifth RDL 335 can thus extend to the another edge of the second singulated bonded structure.

Turning back to FIG. 6, in some implementations, the seventh die 374 of the third device layer 371 is at least partially embedded in a third encapsulant 377. The fourth device layer 381 can also include an eighth die 384. The eighth die 384 can be similar to or different from the fourth die 382. In some implementations, a sixth redistribution layer (RDL) 379 is also formed on the third device layer 371, which can be the same as or generally similar to third RDL 375. The sixth RDL 379 can facilitate the rerouting of electrical connections between the dies (e.g., seventh die 374) and an external interface (e.g., a fourth signal test trace).

The eighth die 384 can be bonded (e.g., directly bonded) to the third device layer 371 along a sixth bonding interface 378. For example, the eighth die 384 can comprise a bonding layer which can be bonded to a bonding layer deposited over the third device layer 371 (e.g., over both the seventh die 374 and the third encapsulant 377). The bonding layer of the third device layer 371 can either be disposed on top of or be part of the sixth RDL 379. In some implementations, the bonding layers can comprise prepared hybrid bonding surfaces and the eighth die 384 is hybrid bonded to the third device layer 371. The sixth bonding interface 378 can be aligned with and/or along the sixth RDL 379. The TSVs 326 can extend through the fifth die 330, the sixth die 332, and/or the seventh die 374 for providing communication between the fifth die 330 and the eighth die 384 (e.g., to or from active circuitry of one die to another).

The sixth RDL 379 of the bonded structure 300 can also include a fourth signal test trace which can be similar to the first signal test trace, second signal test trace, and/or third signal test trace. The sixth RDL 379 comprising the fourth signal test trace can be positioned between the third device layer 371 and the eighth die 384. The fourth signal test trace can be in electrical communication with at least one of the fifth die 330, the sixth die 332, the seventh die 374, and the eighth die 384. The TSVs 326 can extend through the fifth die 330, the sixth die 332, and the seventh die 374 to provide communication between the fifth die 330, the sixth die 332, the seventh die 374, and the eighth die 384 (e.g., to and/or from active circuitry of one die to another). The sixth RDL 379 comprising the fourth signal test trace can extend outwardly from the sixth bonding interface 378. In some implementations, the sixth RDL 379 includes a signal test pad 358 connected to the second signal test trace portion of the sixth RDL 379. The signal test pad 358 can have a width that is wider than the width of the second signal test trace, in some implementations. The sixth RDL 379 comprising the fourth signal test trace can extend beyond functional areas of the third device layer 371 and the eighth die 384 and/or beyond functional areas of the seventh die 374 and the eighth die 384. Additionally, the sixth RDL 379 comprising the fourth signal test trace can extend beyond functional areas of the fifth die 330, the sixth die 332, the seventh die 374, and the eighth die 384. Similar to first signal test trace, the second signal test trace, and the third signal test trace, the fourth signal test trace can be utilized for a variety of testing methods, such as parametric probing, wafer acceptance test (WAT), and/or process control monitoring (PCM), to assess and monitor the quality and/or performance during assembly of the bonded structure 300. The sixth RDL 379 comprising the third signal test trace can be positioned such that during the second singulation of the bonded structure 300, which can occur simultaneously or after the first singulation, a portion of the sixth RDL 379 comprising the fourth signal test trace is removed along the second cutting path, leaving a remaining portion of the sixth RDL 379 comprisign the fourth signal test trace within the another edge of the second singulated bonded structure (e.g., the remaining portion of the fourth signal test trace terminates at another boundary of the third encapsulant 377 such that the remaining portion is flush with the edge of the third encapsulant 377). The remaining portion of the sixth RDL 379 comprising the fourth signal test trace can thus extend to the another edge of the second singulated bonded structure.

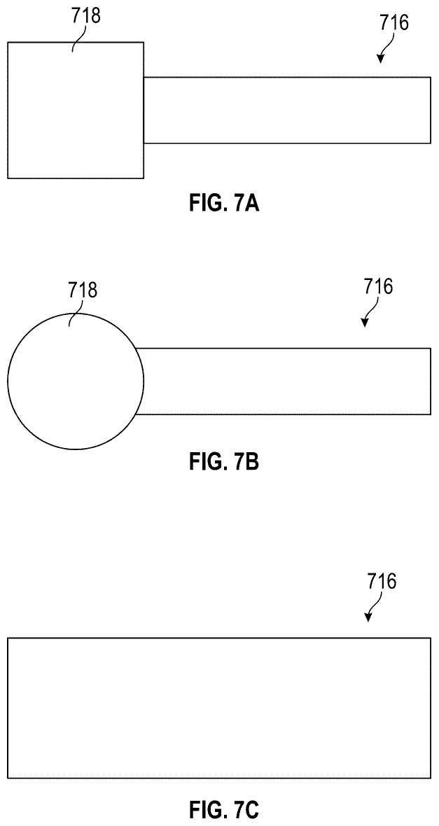

FIGS. 7A-7C illustrate various examples of the signal test traces 716 and signal test pad 718, according to some implementations. A first signal test trace 716 can include a test pad 718 at one end. The first signal test trace 716 can be a conductive pathway for signal testing and troubleshooting. The first signal test trace 716 can run from a circuit point to a test pad 718, an exposed area of conductive material. The test pad 718, which can be located at an accessible spot, can allow test equipment (such as an oscilloscope and/or probe) to make direct electrical contact for signal measurements. Placing the test pad 718 at one end of the first signal test trace 716 can assist with verifying signal integrity, measuring voltage, and detecting potential faults without interfering with other components. As shown in FIGS. 7A and 7B, the first signal test trace 716 can comprise a body having a length greater than its width. The signal test pad 718 can be disposed at one end of the first signal test trace 716. The signal test pad 718 can have a width that is wider than the width of the first signal test trace 716. The signal test pad 718 can comprise a variety of shapes such as a quadrilateral as shown in FIG. 7A, and/or a circle in FIG. 7B. FIG. 7C illustrates a rectangular first signal test trace 716 which does not include a separate signal test pad 718. Rather, the first signal test trace 716 can be widened to improve access and contact for testing. As shown in FIGS. 7A to 7C, the various shapes for the first signal test trace 716 and/or the test pads 718 can enhance the testing process by improving reliability, accessibility, and/or efficiency. Different shapes, such as squares (see FIG. 7A), circles (see FIG. 7B), and rectangles (see FIG. 7C), can improve locating and distinguishing test points, particularly when multiple testing points are close together. Additionally, assigning shapes to certain test functions can creates an intuitive layout, reducing the chance of errors. Certain shapes also improve contact reliability; for instance, circular or square pads can offer a larger surface area for contact, while rectangular pads provide better stability along the length of the probe, reducing testing errors from intermittent connections. Additionally, different probe types may work best with particular pad shapes, allowing for greater adaptability in both manual and automated testing. Using shapes like elongated rectangles can maximize board space without sacrificing pad accessibility. Furthermore, shapes that match the probe design can minimize wear, as better contact requires less pressure, reducing mechanical stress on the first signal test trace 716 and/or signal test pad 718 over time.

### Direct Bonding

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 808a and/or 808b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Many organic adhesives lack strong chemical or covalent bonds with either element. In such processes, the connections between the elements are weak and/or readily reversed, such as by reheating.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In one example conventional metal bonding process, a fusible metal alloy (e.g., solder) can be provided between the conductors of two elements, heated to melt the alloy, and cooled to form the connection between the two elements. The resulting bond often evinces sharp interfaces with conductors from both elements and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

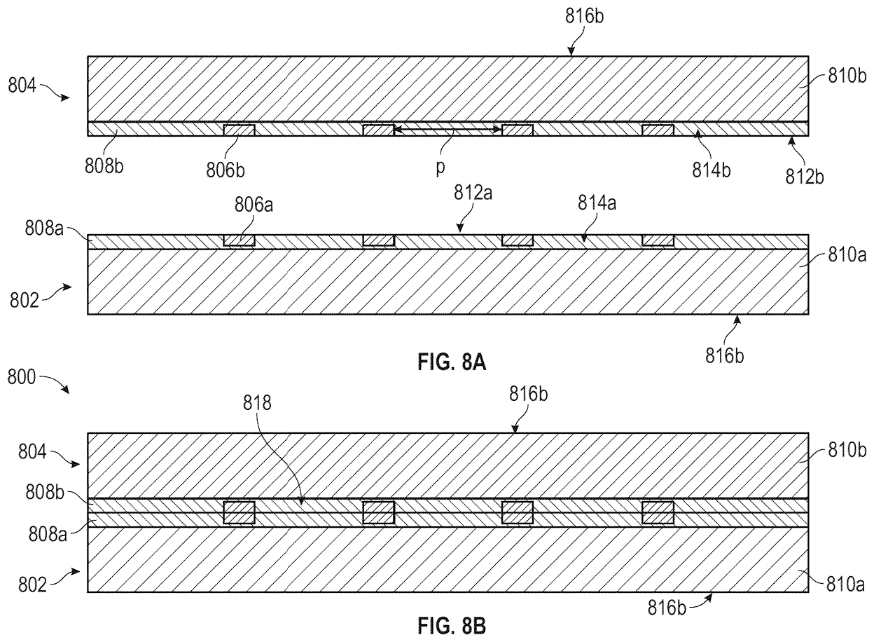

FIGS. 8A and 8B schematically illustrate cross-sectional side views of first and second elements 802, 804 prior to and after, respectively, a process for forming a directly bonded structure, and more particularly a hybrid bonded structure, according to some embodiments. In FIG. 8B, a bonded structure 800 comprises the first and second elements 802 and 804 that are directly bonded to one another at a bond interface 818 without an intervening adhesive. Conductive features 806a of a first element 802 may be electrically connected to corresponding conductive features 806b of a second element 804. In the illustrated hybrid bonded structure 800, the conductive features 806a are directly bonded to the corresponding conductive features 806b without intervening solder or conductive adhesive.

The conductive features 806a and 806b of the illustrated embodiment are embedded in, and can be considered part of, a first bonding layer 808a of the first element 802 and a second bonding layer 808b of the second element 804, respectively. Field regions of the bonding layers 808a, 808b extend between and partially or fully surround the conductive features 806a, 806b. The bonding layers 808a, 808b can comprise layers of non-conductive materials suitable for direct bonding, as described above, and the field regions are directly bonded to one another without an adhesive. The non-conductive bonding layers 808a, 808b can be disposed on respective front sides 814a, 814b of base substrate portions 810a, 810b.

The first and second elements 802, 804 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 802, 804, and back-end-of-line (BEOL) interconnect layers over such semiconductor portions. The bonding layers 808a, 808b can be provided as part of such BEOL layers during device fabrication, as part of redistribution layers (RDL), or as specific bonding layers added to existing devices, with bond pads extending from underlying contacts. Active devices and/or circuitry (not shown) can be patterned and/or otherwise disposed in or on the base substrate portions 810a, 810b, and can electrically communicate with at least some of the conductive features 806a, 806b. Active devices and/or circuitry can be disposed at or near the front sides 814a, 814b of the base substrate portions 810a, 810b, and/or at or near opposite backsides 816a, 816b of the base substrate portions 810a, 810b. In other embodiments, one or both of the elements 802, 804 may not include active circuitry, but may instead comprise dummy elements, passive interposers, passive optical elements (e.g., glass substrates, gratings, lenses), etc. The bonding layers 808a, 808b are shown as being provided on the front sides of the elements, but similar bonding layers can be additionally or alternatively provided on the back sides of the elements.

In some embodiments, the base substrate portions 810a, 810b can have significantly different coefficients of thermal expansion (CTEs), and bonding elements that include such different based substrate portions can form a heterogenous bonded structure. The CTE difference between the base substrate portions 810a and 810b, and particularly between bulk semiconductor (typically single crystal) portions of the base substrate portions 810a, 810b, can be greater than 5 ppm/° C. or greater than 10 ppm/° C. For example, the CTE difference between the base substrate portions 810a and 810b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 810a, 810b can comprise optoelectronic single crystal materials, including perovskite materials, that are useful for optical piezoelectric or pyroelectric applications, and the other of the base substrate portions 810a, 810b comprises a more conventional substrate material. For example, one of the base substrate portions 810a, 810b comprises lithium tantalate (LiTaO3) or lithium niobate (LiNbO3), and the other one of the base substrate portions 810a, 810b comprises silicon (Si), quartz, fused silica glass, sapphire, or a glass. In other embodiments, one of the base substrate portions 810a, 810b comprises a III-V single semiconductor material, such as gallium arsenide (GaAs) or gallium nitride (GaN), and the other one of the base substrate portions 810a, 810b can comprise a non-III-V semiconductor material, such as silicon (Si), or can comprise other materials with similar CTE, such as quartz, fused silica glass, sapphire, or a glass. In still other embodiments, one of the base substrate portions 810a, 810b comprises a semiconductor material and the other of the base substrate portions 810a, 810b comprises other materials, such as a glass, organic or ceramic substrate.

In some arrangements, the first element 802 can comprise a singulated element, such as a singulated integrated device die. In other arrangements, the first element 802 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate (e.g., a laminate substrate, a ceramic substrate, etc.) or a passive or active interposer. Similarly, the second element 804 can comprise a singulated element, such as a singulated integrated device die. In other arrangements, the second element 804 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding layers for both bonded and singulated elements can be coextensive and may include markings indicative of the common singulation process for the bonded structure (e.g., saw markings if a saw singulation process is used).

While only two elements 802, 804 are shown, any suitable number of elements can be stacked in the bonded structure 800. For example, a third element (not shown) can be stacked on the second element 804, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 802. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 808a, 808b, the bonding layers 808a, 808b can be prepared for direct bonding. Non-conductive bonding surfaces 812a, 812b at the upper or exterior surfaces of the bonding layers 808a, 808b can be prepared for direct bonding by polishing, for example, by chemical mechanical polishing (CMP). The roughness of the polished bonding surfaces 812 a, 812 b can be less than 30 Å rms. For example, the roughness of the bonding surfaces 812a and 812b can be in a range of about 0.1 Å rms to 15 Å rms, 0.5 Å rms to 10 Å rms, or 1 Å rms to 5 Å rms. Polishing can also be tuned to leave the conductive features 806a, 806b recessed relative to the field regions of the bonding surfaces 812a, 812b.

Preparation for direct bonding can also include cleaning and exposing one or both of the bonding surfaces 812a, 812b to a plasma and/or etchants to activate at least one of the surfaces 812a, 812b. In some embodiments, one or both of the surfaces 812a, 812b can be terminated with a species after activation or during activation (e.g., during the plasma and/or etch processes). Without being limited by theory, in some embodiments, the activation process can be performed to break chemical bonds at the bonding surface(s) 812a, 812b, and the termination process can provide additional chemical species at the bonding surface(s) 812a, 812b that alters the chemical bond and/or improves the bonding energy during direct bonding. In some embodiments, the activation and termination are provided in the same step, e.g., a plasma to activate and terminate the surface(s) 812a, 812b. In other embodiments, one or both of the bonding surfaces 812a, 812b can be terminated in a separate treatment to provide the additional species for direct bonding. In various embodiments, the terminating species can comprise nitrogen. For example, in some embodiments, the bonding surface(s) 812a, 812b can be exposed to a nitrogen-containing plasma. Other terminating species can be suitable for improving bonding energy, depending upon the materials of the bonding surfaces 812a, 812b. Further, in some embodiments, the bonding surface(s) 812a, 812b can be exposed to fluorine. For example, there may be one or multiple fluorine concentration peaks at or near a bond interface 818 between the first and second elements 802, 804. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 800, the bond interface 818 between two non-conductive materials (e.g., the bonding layers 808a, 808b) can comprise a very smooth interface with higher nitrogen (or other terminating species) content and/or fluorine concentration peaks at the bond interface 818. In some embodiments, the nitrogen and/or fluorine concentration peaks may be detected using various types of inspection techniques, such as SIMS techniques. The polished bonding surfaces 812a and 812b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially smooths out high points on the bonding surface.

The non-conductive bonding layers 808a and 808b can be directly bonded to one another without an adhesive. In some embodiments, the elements 802, 804 are brought together at room temperature, without the need for application of a voltage, and without the need for application of external pressure or force beyond that used to initiate contact between the two elements 802, 804. Contact alone can cause direct bonding between the non-conductive surfaces of the bonding layers 808a, 808b (e.g., covalent dielectric bonding). Subsequent annealing of the bonded structure 800 can cause the conductive features 806a, 806b to directly bond.

In some embodiments, prior to direct bonding, the conductive features 806a, 806b are recessed relative to the surrounding bonding surfaces, such that a total gap between opposing contacts after dielectric bonding and prior to anneal is less than 15 nm, or less than 10 nm. Because the recess depths for the conductive features 806a and 806b can vary across each element, due to process variation, the noted gap can represent a maximum or an average gap between corresponding conductive features 806a, 806b of two joined elements (prior to anneal). Upon annealing, the conductive features 806a and 806b can expand and contact one another to form a metal-to-metal direct bond.

During annealing, the conductive features 806a, 806b (e.g., metallic material) can expand while the direct bonds between surrounding non-conductive materials of the bonding layers 808a, 808b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature. In various embodiments, bonds can form at lower temperatures compared to soldering or thermocompression bonding.

In various embodiments, the conductive features 806a, 806b can comprise discrete pads, contacts, electrodes, or traces at least partially embedded in the non-conductive field regions of the bonding layers 808a, 808b. In some embodiments, the conductive features 806a, 806b can comprise exposed contact surfaces of TSVs (e.g., through silicon vias).

As noted above, in some embodiments, in the elements 802, 804 of FIG. 8A prior to direct bonding, portions of the respective conductive features 806a and 806b can be recessed below the non-conductive bonding surfaces 812a and 812b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 806a, 806b or to average depths of the recesses relative to local non-conductive field regions. Even for an individual conductive feature 806a, 806b, the vertical recess can vary across the surface of the feature, and can be measured at or near the lateral middle or center of the cavity in which a given conductive feature 806a, 806b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 806a, 806b across the direct bond interface 818 (e.g., small or fine pitches for regular arrays).

In some embodiments, a pitch p of the conductive features 806a, 806b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 806a and 806b to one of the lateral dimensions (e.g., a diameter) of the conductive feature is less than 20, or less than 10, or less than 5, or less than 3 and sometimes desirably less than 2. In various embodiments, the conductive features 806a and 806b and/or traces can comprise copper or copper alloys, although other metals may be suitable, such as nickel, aluminum, or alloys thereof. The conductive features disclosed herein, such as the conductive features 806a and 806b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 802, 804, as shown, the orientations of one or more conductive features 806a, 806b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 806b in the bonding layer 808b (and/or at least one internal conductive feature, such as a BEOL feature) of the upper element 804 may be tapered or narrowed upwardly, away from the bonding surface 812b. By way of contrast, at least one conductive feature 806a in the bonding layer 808a (and/or at least one internal conductive feature, such as a BEOL feature) of the lower element 802 may be tapered or narrowed downwardly, away from the bonding surface 812a. Similarly, any bonding layers (not shown) on the backsides 816a, 816b of the elements 802, 804 may taper or narrow away from the backsides, with an opposite taper orientation relative to front side conductive features 806a, 806b of the same element.

As described above, in an anneal phase of hybrid bonding, the conductive features 806a, 806b can expand and contact one another to form a metal-to-metal direct bond. In some embodiments, the materials of the conductive features 806a, 806b of opposite elements 802, 804 can interdiffuse during the annealing process. In some embodiments, metal grains grow into each other across the bond interface 818. In some embodiments, the metal is or includes copper, which can have grains oriented along the 111 crystal plane for improved copper diffusion across the bond interface 818. In some embodiments, the conductive features 806a and 806b may include nanotwinned copper grain structure, which can aid in merging the conductive features during anneal. There is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b.

In the foregoing specification, the systems and processes have been described with reference to specific implementations thereof. It will, however, be evident that various modifications and changes may be made thereto without departing from the broader spirit and scope of the implementations disclosed herein. The specification and drawings are, accordingly, to be regarded in an illustrative rather than restrictive sense.

Indeed, although the systems and processes have been disclosed in the context of certain implementations and examples, it will be understood by those skilled in the art that the various implementations of the systems and processes extend beyond the specifically disclosed implementations to other alternative implementations and/or uses of the systems and processes and obvious modifications and equivalents thereof. In addition, while several variations of the implementations of the systems and processes have been shown and described in detail, other modifications, which are within the scope of this disclosure, will be readily apparent to those of skill in the art based upon this disclosure. It is also contemplated that various combinations or sub-combinations of the specific features and implementations of the implementations may be made and still fall within the scope of the disclosure. It should be understood that various features and implementations of the disclosed implementations can be combined with, or substituted for, one another in order to form varying modes of the implementations of the disclosed systems and processes. Any methods disclosed herein need not be performed in the order recited. Thus, it is intended that the scope of the systems and processes herein disclosed should not be limited by the particular implementations described above.

It will be appreciated that the systems and methods of the disclosure each have several innovative implementations, no single one of which is solely responsible or required for the desirable attributes disclosed herein. The various features and processes described above may be used independently of one another or may be combined in various ways. All possible combinations and sub-combinations are intended to fall within the scope of this disclosure.

Certain features that are described in this specification in the context of separate implementations also may be implemented in combination in a single implementations. Conversely, various features that are described in the context of a single implementation also may be implemented in multiple implementations separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination. No single feature or group of features is necessary or indispensable to each and every implementation.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain implementations include, while other implementations do not include, certain features, elements and/or states. Thus, such conditional language is not generally intended to imply that features, elements and/or states are in any way required for one or more implementations.

While certain implementations have been described, these implementations have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative implementations may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various implementations described above can be combined to provide further implementations. The accompanying claims and their equivalents are intended to cover such forms or modifications as would fall within the scope and spirit of the disclosure.

Several illustrative examples of testing and related systems and methods have been disclosed. Although this disclosure has been described in terms of certain illustrative examples and uses, other examples and other uses, including examples and uses which do not provide all of the features and advantages set forth herein, are also within the scope of this disclosure. Components, elements, features, acts, or steps may be arranged or performed differently than described and components, elements, features, acts, or steps may be combined, merged, added, or left out in various examples. All possible combinations and subcombinations of elements and components described herein are intended to be included in this disclosure. No single feature or group of features is necessary or indispensable.

Certain features that are described in this disclosure in the context of separate implementations may also be implemented in combination in a single implementation. Conversely, various features that are described in the context of a single implementation also may be implemented in multiple implementations separately or in any suitable subcombination. Moreover, although features may be described above as acting in certain combinations, one or more features from a claimed combination may in some cases be excised from the combination, and the combination may be claimed as a subcombination or variation of a subcombination.

Further, while illustrative examples have been described, any examples having equivalent elements, modifications, omissions, and/or combinations are also within the scope of this disclosure. Moreover, although certain aspects, advantages, and novel features are described herein, not necessarily all such advantages may be achieved in accordance with any particular example. For example, some examples within the scope of this disclosure achieve one advantage, or a group of advantages, as taught herein without necessarily achieving other advantages taught or suggested herein. Further, some examples may achieve different advantages than those taught or suggested herein.

Some examples have been described in connection with the accompanying drawings. The figures may or may not be drawn and/or shown to scale, but such scale should not be limiting, since dimensions and proportions other than what are shown are contemplated and are within the scope of the disclosed devices, systems, and methods. Distances, angles, etc. are merely illustrative and do not necessarily bear an exact relationship to actual dimensions and layout of the devices illustrated. Components may be added, removed, and/or rearranged. Further, the disclosure herein of any particular feature, aspect, method, property, characteristic, quality, attribute, element, or the like in connection with various examples may be used in all other examples set forth herein. Additionally, any methods described herein may be practiced using any device suitable for performing the recited steps.

For purposes of summarizing the disclosure, certain aspects, advantages and features of several devices, systems, and methods have been described herein. Not all, or any such advantages are necessarily achieved in accordance with any particular example of the devices, systems, and methods disclosed herein. No aspects of this disclosure are essential or indispensable. In many examples, the devices, systems, and methods may be configured differently than illustrated in the figures. or description herein. For example, various functionalities provided by the illustrated modules may be combined, rearranged, added, or deleted. In some implementations, additional or different processors or modules may perform some or all of the functionalities described with reference to the examples described and illustrated in the figures. Many implementation variations are possible. Any of the features, structures, steps, or processes disclosed in this specification may be included in any example.

As used herein, a phrase referring to “at least one of” a list of items refers to any combination of those items, including single members. As an example, “at least one of: A, B, or C” is intended to cover: A, B, C, A and B, A and C, B and C, and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain implementations require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the implementations shown herein but are to be accorded a fair interpretation consistent with this disclosure, the principles and the novel features disclosed herein.

What is claimed is:

1. A bonded structure comprising:
a first device layer comprising a reconstituted element, the reconstituted element comprising a first die at least partially embedded in an encapsulant;
a second device layer comprising a second die, the second die bonded to the reconstituted element along a first bonding interface; and
a first signal test trace positioned between the reconstituted element and the second die, the first signal test trace in electrical communication with at least one of the first die and the second die, wherein the first signal test trace extends outwardly from the first bonding interface.

2. The bonded structure of claim 1, wherein the first signal test trace is positioned between the first die and the second die.

3. The bonded structure of claim 1, wherein the second die is hybrid bonded to the reconstituted element.

4. The bonded structure of claim 1, wherein the first signal test trace extends to an edge of the bonded structure.

5. The bonded structure of claim 1, wherein the first signal test trace is positioned such that during singulation of the bonded structure, a portion of the first signal test trace is removed along a cutting path, leaving a remaining portion of the first signal test trace within the singulated bonded structure such that the remaining portion of the first signal test trace extends to an edge of the singulated bonded structure.

6. The bonded structure of claim 1, wherein the first signal test trace extends beyond functional areas of the first die and the second die.

7. The bonded structure of claim 1, wherein the reconstituted element of the first device layer further comprises a third die and the second device layer further comprises a fourth die, the fourth die bonded to the reconstituted element along a second bonding interface, wherein a second signal test trace is positioned between the reconstituted element and the fourth die, the second signal trace in electrical communication with at least one of the third die and the fourth die, wherein the second signal test trace extends outwardly from the second bonding interface beyond functional areas of the third die and the fourth die, and wherein the second signal test trace is positioned such that during a second singulation of the bonded structure, a removed portion of the second signal test trace is removed along a second cutting path, leaving a remaining portion of the second signal test trace within the second singulated bonded structure such that the remaining portion of the second signal test trace extends to an another edge of the second singulated bonded structure.

8. A bonded structure comprising:
a first device layer comprising a reconstituted element, the reconstituted element comprising a first die at least partially embedded in an encapsulant;
a second device layer comprising a die stack, the die stack bonded to the reconstituted element along a first bonding interface, wherein the die stack comprises a plurality of dies; and
a first signal test trace positioned between the reconstituted element and the die stack, the first signal trace in electrical communication with at least one of the first die and the die stack, wherein the first signal test trace extends outwardly from the first bonding interface.

9. The bonded structure of claim 8, wherein the die stack is hybrid bonded to the reconstituted element.

10. The bonded structure of claim 8, wherein the first signal test trace extends to an edge of the bonded structure.

11. The bonded structure of claim 8, wherein the first signal test trace is positioned such that during singulation of the bonded structure, a portion of the first signal test trace is removed along a cutting path, leaving a remaining portion of the first signal test trace within the singulated bonded structure such that the remaining portion of the first signal test trace extends to an edge of the singulated bonded structure.

12. The bonded structure of claim 8, wherein the first signal test trace extends beyond functional areas of the first die and the die stack.

13. The bonded structure of claim 8, wherein the reconstituted element of the first device layer further comprises a second die and the second device layer further comprises a second die stack, the second die stack bonded to the second die along a second bonding interface, wherein a second signal test trace is positioned between the reconstituted element and the second die stack, the second signal test trace in electrical communication with at least one of the second die and the second die stack, and wherein the second signal test trace extends outwardly from the second bonding interface beyond functional areas of the second die and the second die stack, and wherein the second signal test trace is positioned such that during a second singulation of the bonded structure, a removed portion of the second signal test trace is removed along a second cutting path, leaving a remaining portion of the second signal test trace within the second bonded structure such that the remaining portion of the second signal test trace extends to an another edge of the singulated bonded structure.

14. A reconstituted structure comprising:
a first device layer comprising a reconstituted element, the reconstituted element comprising a first die at least partially embedded in a first encapsulant;
a second device layer comprising a second die at least partially embedded in a second encapsulant, the second device layer bonded to the first device layer along a first bonding interface and;
a third device layer comprising a third die, the third die bonded to the second device layer along a second bonding interface, wherein through-substrate-vias electrically connect at least one of first die and the second die; and
a first signal test trace positioned between the second device layer and the third die, the first signal test trace in electrical communication with at least one of the first die, the second die, and the third die via the through-substrate-vias, wherein the first signal test trace extends outwardly from the second bonding interface.

15. The reconstituted structure of claim 14, wherein the second device layer is hybrid bonded to the first reconstituted element and the third die is hybrid bonded to the second device layer.

16. The reconstituted structure of claim 14, wherein the first signal test trace is positioned such that during singulation of the bonded structure, a removed portion of the first signal test trace is removed along a cutting path, leaving a remaining portion of the first signal test trace within the singulated bonded structure such that the remaining portion of the first signal test trace extends to an edge of the singulated bonded structure.

17. The reconstituted structure of claim 14, wherein the first signal test trace extends beyond functional areas of the first die, the second die, and the third die.

18. The reconstituted structure of claim 14, further comprising:
the third die of the third device layer at least partially embedded in a third encapsulant;
a fourth die bonded to the third device layer along a third bonding interface, wherein the through-substrate-vias electrically connect the first die, the second die, the third die, and the fourth die; and
a second signal test trace positioned between the third device layer and the fourth die, the second signal test trace electrical communication with at least one of the first die, the second die, the third die, and the fourth die via the through-substrate-vias, wherein the second signal test trace extends outwardly from the third bonding interface beyond functional areas of the first die, the second die, the third die, and the fourth die, and wherein the second signal test trace is positioned such that during singulation of the bonded structure, a removed portion of the second signal test trace is removed along a cutting path, leaving a remaining portion of the second signal test trace within the singulated bonded structure such that the remaining portion of the second signal test trace extends to an edge of the singulated bonded structure.

19. The reconstituted structure of claim 14, wherein the first reconstituted element of the first device layer further comprises a fifth die, the second device layer further comprises a sixth die, and the third device layer comprises a seventh die, wherein the sixth die is bonded to the reconstituted element along a fourth bonding interface and the seventh die is bonded to the second device layer along a fifth bonding interface, wherein through-substrate-vias electrically connect the fifth die, the sixth die, and the seventh die, wherein a third signal test trace is positioned between the second device layer and the seventh die, the third signal test trace in electrical with at least one of the fifth die, the sixth die, and the seventh die via the through-substrate-vias, wherein the third signal test trace extends outwardly from the fifth bonding interface beyond functional areas of the fifth die, the sixth die, and the seventh die, and wherein the third signal test trace is positioned such that during a second singulation of the bonded structure, a removed portion of the third signal test trace is removed along a cutting path, leaving a remaining portion of the third signal test trace within the second singulated bonded structure such that the remaining portion of the third signal trace extends to an another edge of the singulated bonded structure.

20. The reconstituted structure of claim 19, further comprising:
an eighth die bonded to third device layer along a sixth bonding interface, wherein the through-substrate-vias electrically connect the fifth die, the sixth die, and the seventh die, and the eighth die; and
a fourth signal test trace positioned between the third device layer and the eighth die and in electrical communication with at least one of the fifth die, the sixth die, the seventh die, and the eighth die via the through-substrate-vias, wherein the fourth signal test trace extends outwardly from the sixth bonding interface beyond functional areas of the fifth die, the sixth die, the seventh die, and the eighth die, and wherein the fourth signal test trace is positioned such that during a second singulation of the bonded structure, a portion of the fourth signal test trace is removed along a second cutting path, leaving a remaining portion of the fourth signal test trace within the second singulated bonded structure such that the remaining portion of the fourth signal test trace extends to an another edge of the singulated bonded structure.
